(19) United States
(12) Patent Application Publication
(10) Pub. No.: US 2006/0223340 A1
(43) Pub. Date: Oct. 5, 2006

(54) Manufacturing managing method of semiconductor devices and a semiconductor substrate

(75) Inventor: Yoshiyuki Yoneda, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/229,728

(22) Filed: Sep. 20, 2005

(30) Foreign Application Priority Data
Mar. 31, 2005 (JP) 2005-105228

(51) Int. Cl. H01L 21/00

(52) U.S. Cl. 438/800

(57) ABSTRACT

A managing method of manufacturing semiconductor devices is disclosed. The method comprises the steps of: providing at least one tag region on a semiconductor substrate in which plural semiconductor devices have been formed, the tag region being provided with a tag which can read/write information without making physical contact; writing manufacturing managing information of each of the semiconductor devices into the tag without making contact with the semiconductor substrate; and reading the manufacturing managing information from the tag after dividing the semiconductor substrate, and selecting non-defective semiconductor devices based on the manufacturing managing information.

### BACKGROUND OF THE INVENTION

1. Field of the Invention

The present invention relates to a manufacturing managing method of semiconductor devices and a semiconductor substrate, and such a manufacturing managing method of semiconductor devices and a semiconductor substrate suitable for manufacturing wafer level packages.

2. Description of the Related Art

In wafer level CSP (Chip Size Package) processing using copper re-routes, chips are, generally, not individualized even after the completion of wafer processing and they go to packaging steps (wafer level packaging steps). Between packaging steps, visual inspection is performed on a wafer by wafer basis.

In this visual inspection, a paper map is created based on wafer effective device layout, and an inspector writes inspection results (mode, etc.) of packaging steps inside and outside and their positions on the paper map. Alternatively, an automatic visual inspecting machine is used to convert the inspection results (mode, etc.) and their positions to electronic data. These data are added as inspection map data to the manufactured product, and new inspection data are continuously added or failure data are collected and superposed as electronic data.

Further, such wafer level CSP processing can be inspected on a wafer by wafer basis, since it is treated on a wafer by wafer basis until being diced into individual chips. As a result of this wafer level inspection, positions of non-defective chips on the wafer can be obtained and a tester can output a non-defective chip map as electronic data.

The non-defective chip map output from the tester is superposed with the above mentioned inspection results to create a final non-defective chip map. Based on the final non-defective chip map, non-defective chips are picked up after dicing.

In order to pick up non-defective chips, the non-defective chip map and the wafer should be correlated in advance. Therefore, each wafer is provided with a unique identification label (wafer ID), and this wafer ID is used for collating a paper map or electronic data. The wafer ID is generally imprinted on a circuit face of the wafer. Recently IC tags as disclosed in Patent Documents #1, #2 are proposed, too.

In the wafer level packaging steps, since an insulating resin and wiring metal layer are formed on the circuit face, it is difficult to identify such an IC tag. In this case, the wafer ID is also written on a backside face.

[Patent Document #1] Japan Patent Laid-Open Application 2004-179234

[Patent Document #2] Japan Patent Laid-Open Application 2004-157765

### PROBLEM(S) TO BE SOLVED BY THE INVENTION

In the prior art manufacturing methods, a wafer is provided with only a wafer ID or IC tag for identifying the wafer. Defect data of each semiconductor device detected by inspections, lot numbers, operation recipe, etc. (referred to as “manufacturing managing information” hereinafter) are not written on the wafer, but separately recorded.

Therefore, in order to pick up non-defective devices at the final step, the wafer ID label and the non-defective device map including the manufacturing managing information should be collated. It is, however, difficult to perform this collation process for each wafer, and it is tedious to perform collation between the non-defective device map and each semiconductor device. Therefore, the prior art manufacturing managing methods have problems in that the management is complicated and tedious, and identification error can easily occur.

### SUMMARY OF THE INVENTION

It is a general object of the present invention to provide a manufacturing managing method of a semiconductor device in which highly accurate manufacturing managing can be easily obtained and a semiconductor substrate using such a manufacturing managing method.

Features and advantages of the present invention are set forth in the description that follows, and in part will become apparent from the description and the accompanying drawings, or may be learned by practice of the invention according to the teachings provided in the description. Objects as well as other features and advantages of the present invention will be realized and attained by a manufacturing managing method particularly pointed out in the specification in such full, clear, concise, and exact terms as to enable a person having ordinary skill in the art to practice the invention.

To achieve these and other advantages and in accordance with the purpose of the invention, as embodied and broadly described herein, the invention provides as follows.

The present invention provides a manufacturing managing method of semiconductor devices, comprising the steps of:

providing at least one tag region on a semiconductor substrate in which a plurality of semiconductor devices is formed, the tag region being provided with a tag which can read/write information without being physically contacted;

writing manufacturing managing information of each of the semiconductor devices into the tag without contacting the semiconductor substrate; and

reading the manufacturing managing information from the tag after dividing the semiconductor substrate, and selecting non-defective semiconductor devices based on the manufacturing managing information.

According to another aspect of the present invention, there is provided a semiconductor substrate comprising a plurality of semiconductor devices and a tag region including a tag from/into which information can be read/written.

### BRIEF DESCRIPTION OF THE DRAWINGS

FIG. 1 is a top plan view of a wafer having a tag region;

FIG. 2 is a flowchart illustrating a manufacturing managing method according to an embodiment of the present invention;

FIG. 3 is a cross-sectional view of wafer level CSP processing having a tag region according to a first embodiment of the present invention;

FIG. 4 is a cross-sectional view of wafer level CSP processing having a tag region according to a second embodiment of the present invention;

FIG. 5A is a cross-sectional view of wafer level CSP processing having a tag region according to a third embodiment of the present invention;

FIG. 5B is a schematic view of an antenna portion of the third embodiment of the present invention;

FIG. 6A is a cross-sectional view of wafer level CSP processing having a tag region according to a fourth embodiment of the present invention;

FIG. 6B is a schematic view of an antenna portion of the fourth embodiment of the present invention; and

FIG. 7 is a flowchart for illustrating a method of manufacturing the wafer level CSPs of the fourth embodiment of the present invention.

### DESCRIPTION OF THE PREFERRED EMBODIMENTS

In the following, embodiments of the present invention are described with reference to the accompanying drawings.

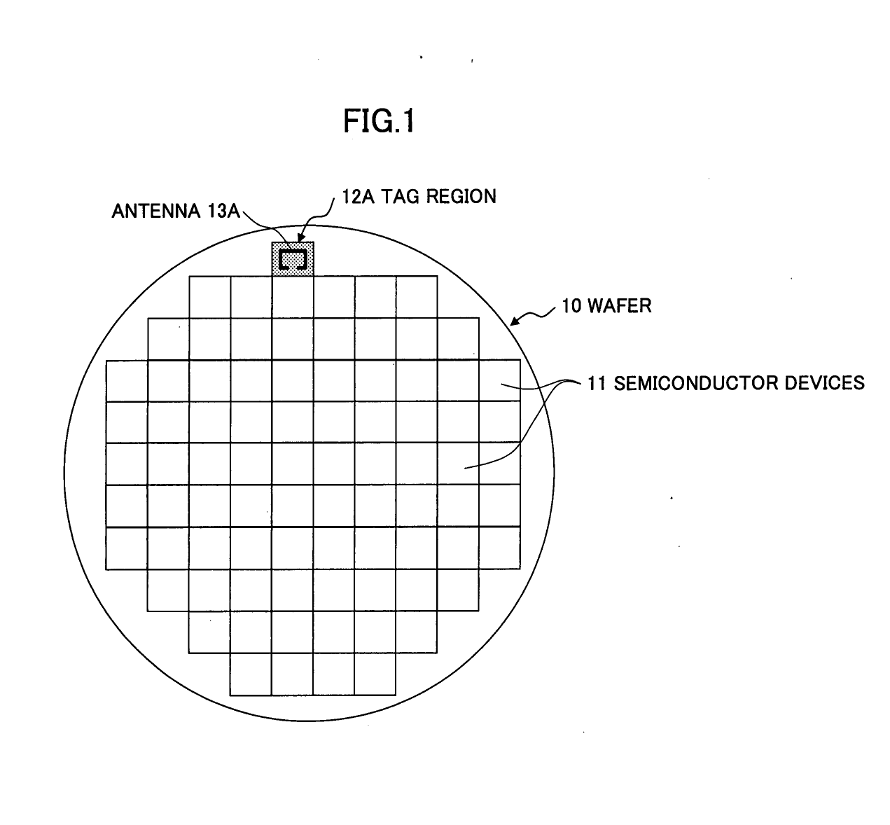

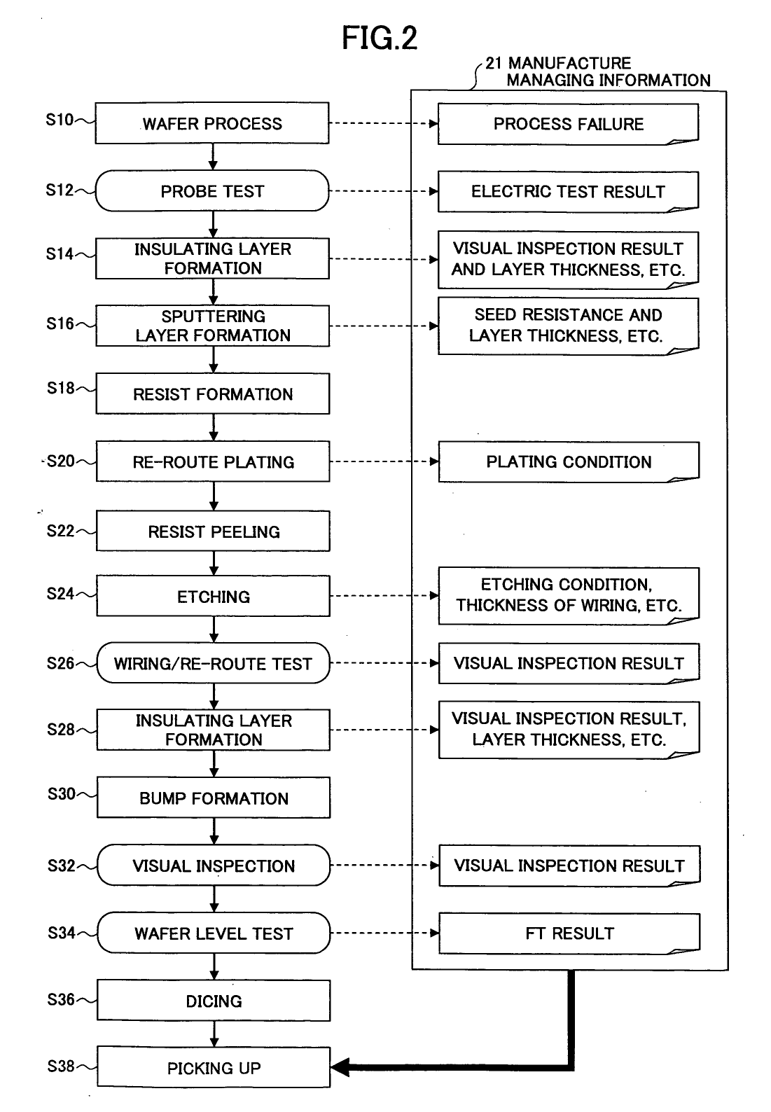

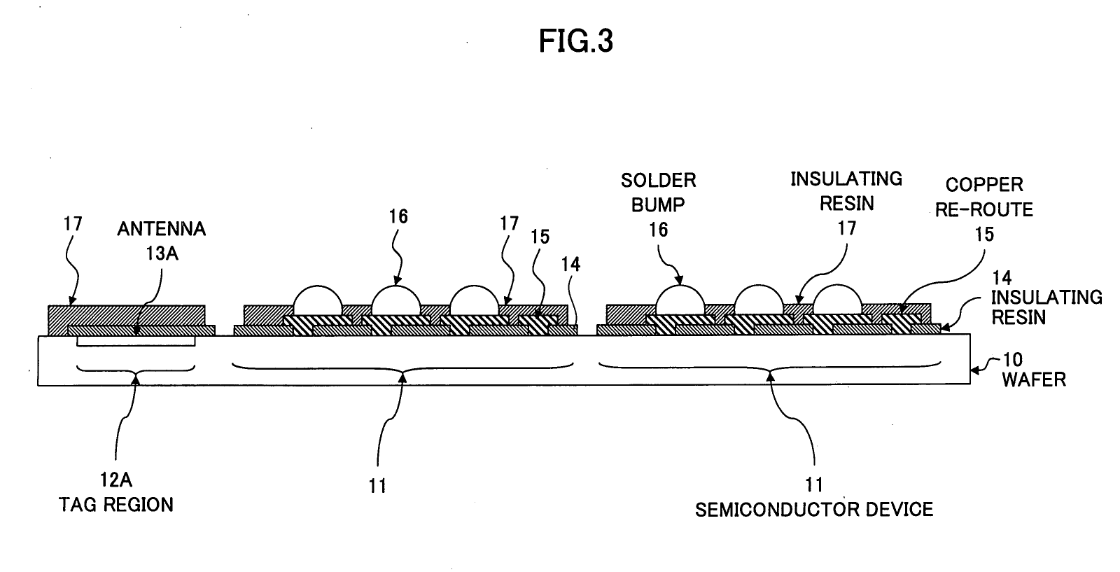

FIGS. 1 through 3 explain a method for managing semiconductor device manufacture according to a first embodiment of the present invention. FIG. 1 shows a wafer 10 just after a wafer process is completed. FIG. 2 is a flowchart illustrating a method for manufacturing wafer level CSPs (semiconductor devices) using the method for managing semiconductor device manufacture according to this embodiment of the present invention. FIG. 3 shows an example of wafer level CSPs manufactured by the method for managing semiconductor device manufacture according to this embodiment of the present invention. This embodiment is explained with reference to the method for managing the manufacture of the wafer level CSPs (semiconductor devices) as shown in FIGS. 1 through 3.

FIG. 1 shows the wafer 10 just after the wafer process shown at step S10 in FIG. 2 is finished. On the wafer 10, many semiconductor devices 11 are formed by the wafer process.

On the surface of the wafer 10 which forms the semiconductor devices 11, a tag region 12A is provided. On the tag region, at least one tag (Radio Frequency Identification) is formed. Information can be written into and read from the tag without physically contacting the tag. FIG. 1 shows only one tag. This tag region 12A is formed at an adequate place on the wafer 10 so that the tag will not interfere with the semiconductor devices 11. Therefore, the tag region 12A on the wafer 10 has no harmful influence on the region where the semiconductor devices 11 are formed.

In this embodiment, the tag is formed together with the semiconductor devices 11 at step S10 in the wafer process. The tag is provided with an antenna 13A which is used for wirelessly reading and writing information from and to the outside with electromagnetic induction or electromagnetic wave communication. In this embodiment, the antenna 13A is also formed together with the semiconductor devices 11 at step S10 in the wafer process. Therefore, there is no need to have an additional step dedicated to the formation of the antenna 13A, and the process for manufacturing semiconductor wafers is simplified.

A wafer level packaging process (a treatment for completing all packaging processes under wafer conditions) shown at steps S10˜S34 in FIG. 2 is performed on the wafer 10 shown in FIG. 1 to form wafer level CSPs shown in FIG. 3.

On the wafer 10 of the wafer level CSPs shown in FIG. 3, plural wafer devices 11 are formed. FIG. 3 only shows two wafer devices 11 for simplicity.

The plural wafer devices 11 are formed by performing the above mentioned wafer process on an upper surface of the wafer 10 made of silicon at step S10. The antenna 13A is also formed in the tag region 12A on the wafer 10 during the wafer process at step S10. On the upper surface of the wafer 10, insulating resin layers 14, 17, copper re-routes 15 and solder bumps 16 are formed.

The insulating resin layer 14 is formed on the upper surface of the wafer 10 in which the semiconductor devices 11 and the antenna 13A have been already formed.

Apertures are opened at predetermined positions of the insulating resin layer 14 for electrically connecting to electrodes formed on the wafer 10. This insulating resin layer 14 covers an upper surface of the antenna 13A in the tag region 12A.

On the insulating resin layer 14, the copper re-routes 15 are formed. The copper re-routes 15 are electrically connected to the electrodes formed on the wafer 10 through the apertures opened in the insulating resin layer 14. On the copper re-routes 15, an insulating resin layer 17 is formed.

Apertures are formed in this insulating resin layer 17 at predetermined positions corresponding to the copper re-routes 15. In the apertures, the solder bumps 16 are placed. In this manner, the wafer level CSPs are formed during the process for manufacturing semiconductor devices 11.

The tag is formed in the tag region 12A as mentioned above; this tag is a memory device, from and to which information can be wirelessly read and written through the antenna 13A to and from the outside.

Next, with reference to FIG. 2, a process for manufacturing wafer level CSPs and its managing method according to the embodiment of the present invention is explained below.

A wafer process at step S10 shown in FIG. 2 is a so-called pre-process in the semiconductor manufacturing process. By performing this wafer process, the semiconductor devices 11 and the tag region 12A (including the antenna 13A) are formed on the wafer 10. In this wafer process, process failure may happen, which becomes the cause of wafer level CSP failures or defects. In the prior art, the process failure information is written in the non-defective device map.

On the other hand, in the embodiment of the present invention, the wafer 10 is provided with the tag region 12A having the tag (not shown) and the antenna 13A is further formed by the completion of the wafer process, and therefore such process failure can be immediately written into the tag. According to this embodiment, at the completion of the wafer process, the process failure is written as one of the manufacture managing information items 21, into the tag.

This writing process is performed by a transmitting apparatus provided in a manufacturing apparatus or an inspection apparatus used for the wafer process. If this transmitting apparatus is in the manufacturing apparatus, it is preferably provided in a manufacturing apparatus used for the last process. The transmitting apparatus may be provided in a handling apparatus which carries the wafer 10.

In a succeeding probe test step (step S12), a probe connected to a tester is put in contact with the electrodes formed on the wafer 10 to perform an electric test. An electric test result is written into the tag as one of the manufacture managing information items 21.

In an insulating layer forming step (step S14) for forming the insulating resin layer 14 on the wafer 10, resin material is applied on the wafer 10, exposed, developed and inspected to form the insulating layer 14. In this insulating layer forming step, a visual inspection result and a layer thickness are written as manufacture managing information 21 into the tag.

Steps S16 through S26 are steps for forming copper re-routes 15. In a sputter layer forming step (Step S16) among these steps, a seed layer (Ti/Cu or Cr/Cu) is formed by sputtering, which has a role as a power supplying layer and a close contacting layer for plating the copper re-routes 15. In this layer forming sputtering step, a seed resistance and thickness of the seed layer, and the serial number of the machine used are written in the tag as manufacture managing information 21.

In a re-route plating step (step S20), power is supplied from a plating apparatus using the seed layer formed in step S16 as an electrode, to perform electrolytic copper plating for forming the copper re-routes 15. In this re-route plating step, the plating condition, etc. is written in the tag as manufacture managing information.

In this re-route plating step, it is possible to prevent operational mistakes by reading out the manufacture managing information 21 from the tag and reading out machine recipes such as plating conditions or etching conditions for each wafer.

In an etching step (step S24), the seed layer formed in the sputtering step is etched, and the electrically connected re-routes are separated by the seed layer to finish. In this etching step, etching conditions and a test result such as a thickness of wiring formed after the etching step are written in the tag as manufacture managing information 21.

After forming the copper re-routes 15 in the above manner, visual inspection (step S26) is performed on the copper re-routes 15 or the insulating layer 14. A result of this visual inspection is also written in the tag as manufacture managing information 21. Failure or defects in the re-routes or the insulating layer can be inspected by human eyes or detected by an automatic visual inspecting apparatus; these failures are utilized for making an electro map.

Step 30 and step 32 are steps for forming the solder bumps 16. After the solder bumps 16 are formed by a well known method (step S30), a visual inspection step (Step S32) is performed to inspect whether the formed solder bumps have predetermined shapes. The size and shape of the bumps are checked in this step. A result of the visual inspection or size abnormality of the solder bumps are utilized to form the electronic map and written in the tag as manufacture managing information.

By performing the above steps S10˜S32, the wafer level CSPs are formed on the wafer 10. In a succeeding step S34, a wafer level final test (FT) is performed on the wafer level CSPs formed on the wafer 10. A test result of the final test is also written into the tag together with failure determination results and defect category as the manufacture managing information 21.

After the above steps S10˜S34 are completed and the plural CSPs (semiconductor devices) are formed on the wafer 10, a dicing step (step S36) is performed to individualize the wafer 10 into single CSPs. This dicing step is done by sticking the wafer on dicing tape and dicing it with a dicing blade. Immediately after the dicing is finished, the CSPs are individualized but still stuck to the dicing tape.

Next, the sticking force of the sticking agent of the dicing tape is weakened by exposing it to ultraviolet light, for example, and each individualized CSP is picked up by a picking up apparatus (step S38). The picking up apparatus has a reading apparatus which reads out the manufacture managing information 21 written into the tag in the tag region 12A. Therefore, the picking up apparatus picks up only non-defective CEPs, based on the manufacture managing information 21 written into the tag.

As mentioned above, in the manufacture managing system according to the embodiment of the present invention, since the manufacture managing information 21 (so-called non-defective semiconductor map) is written in the tag formed on the wafer 10, the wafer 10 goes through each step (steps S12˜S38) while holding the manufacture managing information 21. If each step has an apparatus for reading and writing tag information, the previous steps' manufacture managing information 21 can be read out by the apparatus in each subsequent step and can be utilized in treating and testing in each subsequent step. That is, each apparatus can provide its manufacture managing information for use in the following steps.

In this embodiment of the present invention, since the manufacture managing information 21 (including information of the semiconductor devices 11) of CSPs formed on the wafer 10 is written into the tag, selection of non-defective devices is simplified and its accuracy is improved, compared with the prior art methods where a map formed separately from the wafer is checked with the wafer to select non-defective devices. Further, after the dicing step (S36), it is possible to keep the individualized tag region 12A. In this case, the history of the wafer 10 can be retained, which is effective in tracing.

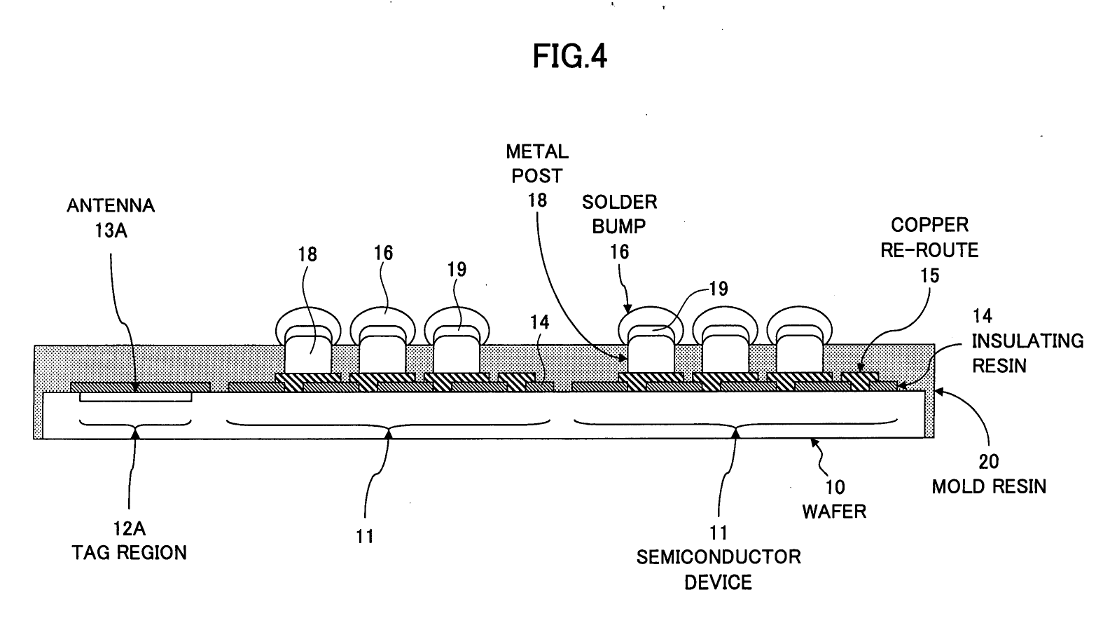

Next, with reference to FIGS. 4 through 7, another embodiment of a wafer level CSP process to which the present invention can be applied is explained below. Another embodiment of an antenna formed in the tag region is explained below. In FIGS. 4 through 7, elements or parts the same as or similar to those in FIGS. 1 through 3 are assigned the same reference numbers and their explanations are omitted.

In a wafer level CSP process shown in FIG. 4, metal posts 18 are formed on copper re-routes 15. Then solder bumps 16 are formed on the metal posts 18 via barrier metals 19. A mold resin layer 20 is formed so as to cover the metal posts 18.

In this structure, the metal posts 18 provide a stress releasing effect. The mold resin layer 20 supports the metal posts 18, and therefore under fill resin is not required in CSP mounting. A tag region 12A in this embodiment is the same as that shown in shown in FIG. 3, and comprises a tag and an antenna 13A, which are formed in a wafer process (step S10, see FIG. 2).

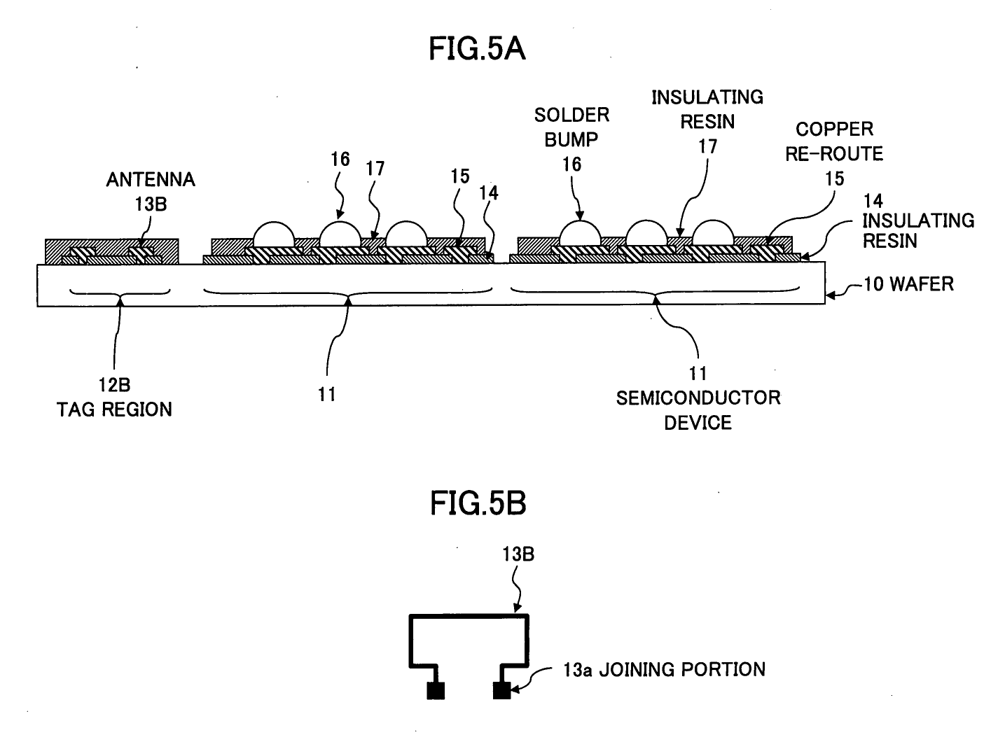

A wafer level CSP process shown in FIG. 5 is similar to that shown in FIG. 3, but is characterized in that an antenna 13B is formed together with copper re-routes 15 during a copper re-route forming step (S16˜26). A tag is formed in a wafer process (step S10, see FIG. 2), the same as in the first embodiment.

The antenna 13B is formed within tag region 12B. Electric connection between the tag and the antenna 13B is performed by connecting a joining portion 13a formed at an edge of the antenna 13B to a tag electrode (not shown) via an aperture formed in the insulating resin 14.

According to this structure, since the tag is formed in the wafer process (Step S10), and the antenna 13B is formed together with the copper re-routes 15, there is no need to have a unique step dedicated to forming the tag 12B and the manufacturing process can be simplified.

In the above embodiments, the tags are formed integrally with the wafer 10 during the wafer process (step S10).

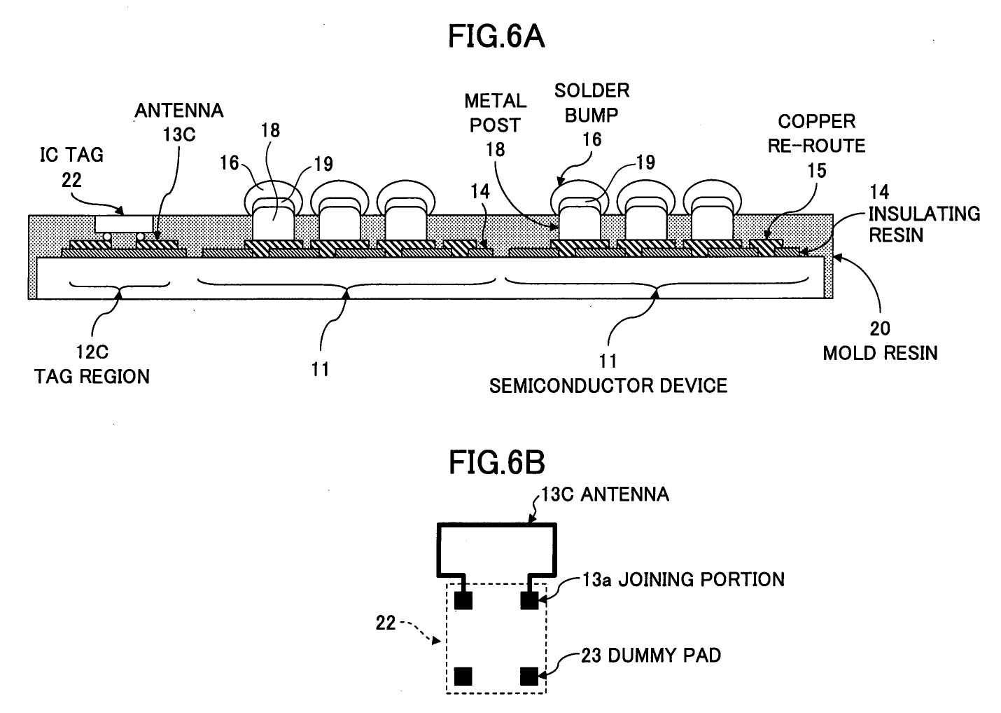

On the other hand, the wafer level CSP process shown in FIG. 6 is characterized in that a tag comprises an IC tag 22 which is a chip part.

An antenna 13C is formed on an upper surface of an insulating resin layer 14, during a step of forming copper re-routes 15. At the same time of forming the antenna 13C, joining portions 13a connected to a tag region 12C are formed and dummy pads 23 on which an IC tag 22 is mounted is formed, as shown in FIG. 6B.

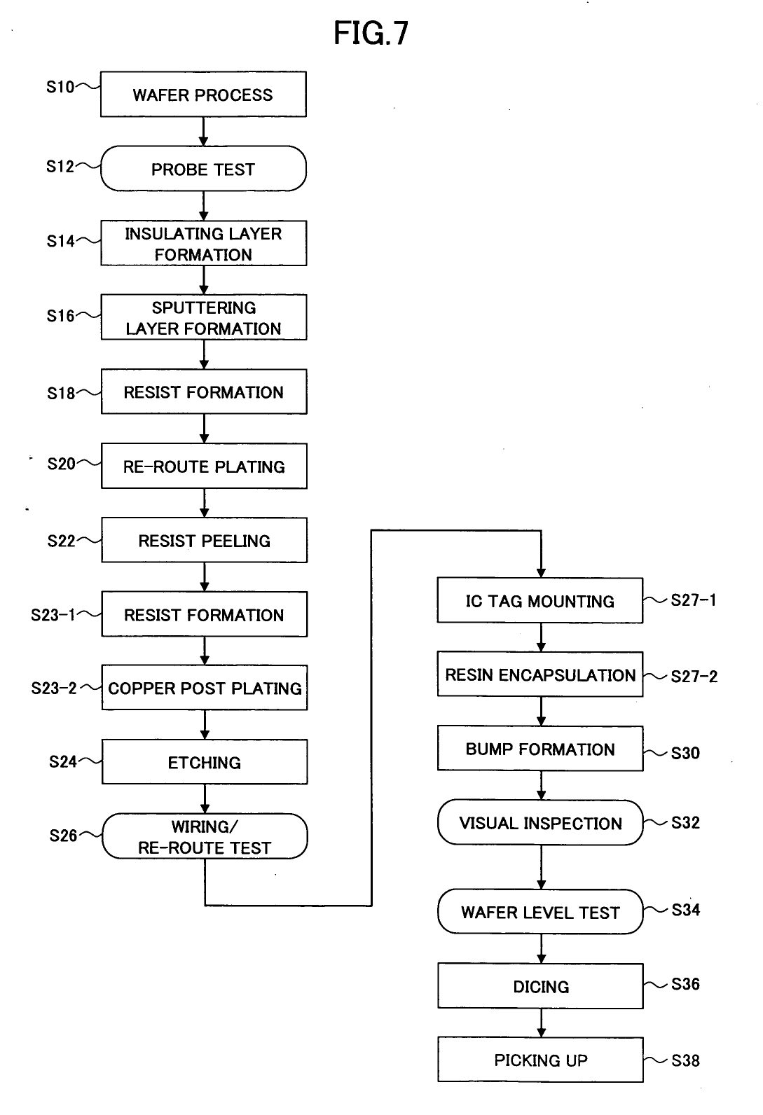

FIG. 7 is a flowchart illustrating a method of manufacturing wafer level CSPs. In FIG. 7, steps the same as those shown in FIG. 2 are assigned the same step numbers and their explanations are omitted.

In this embodiment of a manufacturing method, after processes for forming copper re-routes 15 (steps S16˜S26) are completed, the metal posts 18 are formed by performing a resist treating step (step S23-1) and a copper post plating step (step S23-2). At this timing, an antenna 13C and dummy pads 23 are formed together in the steps of forming the copper re-routes 15 (step S16˜S26).

In this embodiment, after the wiring test step (S26) is completed, an IC tag 22 is mounted in step S27-1. This mounting step is done by using the mounting type of IC tag 22 and flip-chip-joining it to the joining portions of the antenna 13C and the dummy pads 23. In succeeding step S27-2, a mold resin layer 20 is formed on the wafer on which the IC tag 22 has been mounted, and the IC tag 22 is securely fixed to the wafer 10.

In the embodiment of the manufacturing method, general purpose parts can be used as an IC tag 22, and the tag does not have to be formed in the wafer process (step S10); therefore, the number of steps (workload) in the wafer process can be decreased.

According to the above embodiments, non-defective semiconductor chips can be picked up easily with high accuracy, compared with the prior art using a separate map.

Further, the present invention is not limited to the embodiments, but variations and modifications may be made without departing from the scope of the present invention.

The present application is based on Japanese Priority Application No. 2005-105228 filed on Mar. 31, 2005 with the Japanese Patent Office, the entire contents of that are hereby incorporated by reference.

What is claimed is:

1. A managing method of manufacturing a plurality of semiconductor devices, comprising the steps of:
providing at least one tag region on a semiconductor substrate in which the semiconductor devices are formed, the tag region being provided with a tag which can read/write information without being contacted;
writing manufacturing managing information of each of the semiconductor devices into the tag without contacting the semiconductor substrate; and
reading the manufacturing managing information from the tag after dividing the semiconductor substrate, and selecting non-defective semiconductor devices based on the manufacturing managing information.

2. The manufacturing managing method as claimed in claim 1, wherein
all of or a part of manufacturing apparatuses used in manufacturing processes of the semiconductor devices are provided with a reader/writer which can read/write information from/into the tag without making contact.

3. The manufacturing managing method as claimed in claim 1, wherein
the manufacturing managing information includes test/inspection information of the semiconductor devices.

4. The manufacturing managing method as claimed in claim 1, wherein
the semiconductor device, re-routes, and solder electrodes are formed on the semiconductor substrate by a wafer level packaging step.

5. The manufacturing managing method as claimed in claim 1, wherein
the tag region is formed at a position so that the tag region does not interfere with the semiconductor devices on the semiconductor substrate.

6. The manufacturing managing method as claimed in claim 1, wherein
the tag region includes a storage element, and the storage element is formed in a step of manufacturing the semiconductor devices.

7. The manufacturing managing method as claimed in claim 1, wherein
the tag region includes an antenna connected to the tag.

8. The manufacturing managing method as claimed in claim 7, wherein
the antenna is formed in a step of manufacturing the semiconductor devices or a step of forming re-routes.

9. The manufacturing managing method as claimed in claim 7, wherein
the tag is a tag chip mounted on the antenna.

10. A semiconductor substrate comprising a plurality of semiconductor devices and a tag region including a tag from/into which information can be read/written.
